(19) United States
(12) Patent Application Publication
(10) Pub. No.: US 2007/0231941 A1
(43) Pub. Date: Oct. 4, 2007

(54) Method of Manufacturing Organic Device Element

(75) Inventor: Hiroshi Sugai, Funabashi-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/686,008

(22) Filed: Mar. 14, 2007

(30) Foreign Application Priority Data
Mar. 30, 2006 (JP) 2006-092893
Jan. 22, 2007 (JP) 2007-010959

(51) Int. Cl. H01L 21/00

(52) U.S. Cl. 438/29

(57) ABSTRACT

An organic device element including a high-quality protective film is manufactured. In a step of forming a protective film on an organic device substrate on which an organic device is formed, an electroconductive rear plate provided on a rear side of the organic device substrate is divided into a peripheral portion which is in contact with a substrate circumference portion and a central portion which is in contact with a substrate central portion. A bias voltage of −10 V is applied to the central portion and a bias voltage of −5 V is applied to the peripheral portion. Therefore, an electric field intensity of a surface of the organic device substrate caused by a discharge unit is made uniform over the entire substrate to reduce a film thickness distribution of the formed protective film to ±2%.

### BACKGROUND OF THE INVENTION

1. Field of the Invention

The present invention relates to a method of manufacturing an organic device element such as an organic electroluminescence (EL) device or an organic field-effect transistor (FET).

2. Description of the Related Art

It is known that an organic EL device includes an organic device (organic EL device) having a pair of electrodes and an organic compound layer interposed therebetween and a protective film (passivation film) provided on the organic device (see Japanese Patent Application Laid-Open No. 2003-217829). The organic device has extremely low resistance to moisture and oxidation resistance. Therefore, in order to maintain the characteristics of the organic device, high resistance to moisture and oxygen is required for the protective film. In addition, the organic device is extremely weak to heat or plasma damage during the formation of the protective film. Therefore, there is a weak point that the organic device is deteriorated by the influence, so that sufficient characteristics cannot be achieved.

According to conventional film formation techniques, a method of forming the protective film which is resistant to moisture and oxygen on a member to be protected at high temperatures and low pressures by sputtering or CVD has been employed. For example, techniques using sputtering or plasma CVD are disclosed in Japanese Patent Application Laid-Open Nos. 2004-339581 and 2004-006444.

However, it is necessary to form the protective film for the organic device such as the organic EL device at temperatures low enough to prevent deterioration of an organic compound in a condition in which plasma damage is small. When the protective film for the organic device is to be formed by the conventional techniques, the organic compound is altered or decomposed by heat deterioration or plasma damage. In order to prevent this, the protective film is formed in low-temperature conditions or low-power conditions. In this case, it is difficult to obtain a protective film which has high resistance to moisture and is dense. In addition, plasma is influenced by the shape of a substrate and the shape of a discharge space, which is likely to cause unevenness in film thickness. Therefore, moisture resistance performance which is a characteristic of the protective film cannot be stably obtained.

### SUMMARY OF THE INVENTION

The present invention has been made in view of the unsolved problems in the above-mentioned conventional techniques. Therefore, an object of the present invention is to provide an organic device element manufacturing method capable of forming a protective film having stable moisture resistance performance on an organic device.

According to the present invention, there is provided a method of manufacturing an organic device element including a substrate, an organic device, and a protective film covering the organic device, the organic device including a pair of electrodes and an organic compound layer provided between the pair of electrodes, the method including forming the protective film on the organic device provided on the substrate, in which the protective film is formed on the organic device provided on the substrate while separate bias voltages are applied to a central region overlapped with the substrate and a peripheral region corresponding to a peripheral portion of the central region, of an electroconductive member provided on a rear side of the substrate.

The term “an organic device” used herein refers to one including a substrate, a pair of electrodes and an organic compound layer provided between the electrodes. The term “an organic device element” refers to one including the organic device and a protective film provided on the organic device.

In the case of forming the protective film, an electric field intensity with regard to the substrate surface on which a film is formed can be made uniform between the center portion and the peripheral portion on a surface of the substrate. Therefore, an absolute value of a film thickness distribution of the protective film can be reduced to 2% or less, so an organic device element having high moisture resistance performance can be realized.

Further features of the present invention will become apparent from the following description of embodiments with reference to the attached drawings.

### BRIEF DESCRIPTION OF THE DRAWINGS

FIG. 1 is an explanatory diagram for an example of the present invention.

FIG. 2 is an explanatory diagram for a comparative example.

FIG. 3 is a graph illustrating a difference between film thickness distributions of protective films in the example of the present invention and the comparative example.

FIG. 4 is a cross sectional photograph of the protective film formed in the example of the present invention.

FIG. 5 is a cross sectional photograph of the protective film formed in the comparative example.

### DESCRIPTION OF THE EMBODIMENTS

An embodiment for carrying out the present invention will be described with reference to the attached drawings.

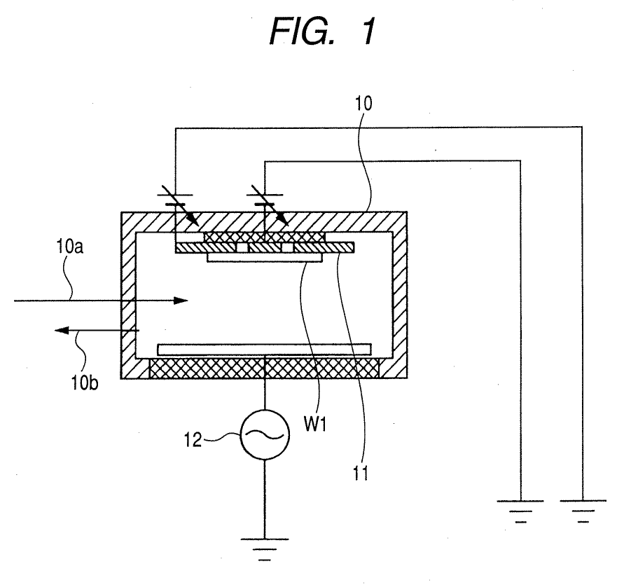

As shown in FIG. 1, a chamber 10 is used to form a protective film covering an organic device of an organic device element such as an organic EL device or an organic FET by plasma discharge caused by a sputtering method or a chemical vapor deposition (CVD) method. The chamber 10 is normally defined by an electroconductive enclosure and maintained at the earth potential. Plasma is confined in the chamber 10. The protective film is deposited on an organic device substrate W₁ including a substrate and the organic device formed thereon. The chamber 10 includes a gas supply unit 10a for introducing a process gas thereinto and an exhaust unit 10b. The protective film is a film obtained by depositing, on the organic device, components which are used as raw materials and electrically charged in the chamber 10.

A surface potential of the organic device substrate W₁ is different from a potential of the enclosure located therearound. When the protective film is to be formed on an organic device having a dielectric, a film formation rate is changed between a peripheral portion of the substrate and a center portion thereof which are influenced by the potential of the enclosure. Therefore, it is difficult to form a protective film having a uniform film thickness and uniform quality.

In order to uniformly attract the electrically charged components to the organic device, an electroconductive rear plate 11 is provided. The electroconductive rear plate 11 includes two separate electroconductive parts corresponding to a center portion and a peripheral portion on a rear surface of the organic device substrate W₁. The rear plate is a plate provided on an opposite side to a film-formed surface of the substrate. The film-formed surface of the substrate is a surface provided on a side on which the organic device element is provided in this embodiment. The formation of a film on the film-formed surface of the substrate means that the organic device can be covered with the film.

The rear plate is electroconductive, so separate bias voltages can be applied to respective regions. To be more specific, the electroconductive rear plate is divided into a central region and an outer region. The substrate is provided on the central region of the surface of the electroconductive rear plate and overlapped therewith. The outer region is not overlapped with the substrate. The outer region without overlap is more specifically a frame-shaped region with a width. The separate bias potentials can be applied to the respective regions of the electroconductive rear plate.

Controlled bias voltages are applied to the respective conductive parts of the electroconductive rear plate 11 such that the substrate potential during the formation of the protective film using a discharge unit 12 is uniform within the surface of the substrate (between the center of the substrate and the periphery of the substrate) For example, voltages which are different from each other by 20% or more are applied to the respective electroconductive parts.

At this time, the substrate may be provided such that the film-formed surface is directed downward.

Therefore, the uniform protective film can be formed on the organic device. Of particles present in a plasma space, particles which may be used as the components of the protective film are uniformly attracted to the organic device to form a deposited film without distortion, so that moisture resistance performance which is a characteristic of the protective film is improved. The protective film is made uniform for an organic EL device, whereby there is also an advantage that uniform light emission without luminance unevenness can be obtained.

The moisture resistance performance which is a characteristic of the protective film is more specifically performance in which a dark spot does not occur at the time of light emission after the device sealed with the protective film is left at a constant temperature of 60° C. and a high humidity of 90% for an accelerated endurance time of 500 hours or more. More desirable performance is performance in which the dark spot does not occur at the time of light emission after the lapse of time of 1000 hours or more. The endurance time of 500 hours or more is a numerical value which can be realized only when film formation is performed while bias voltages are applied such that a substrate potential is uniform between the center portion and the peripheral portion into which the organic device substrate is divided.

In addition, the bias voltages are applied to control a potential of an object on which the protective film is directly deposited. As a result, there is an advantage that a film formation rate becomes higher. To be more specific, a state in which the bias voltages are applied means that the potential of the object is changed from the plasma potential by a potential difference of 1 V or more.

The object on which the protective film is directly deposited is at least one of the pair of electrodes of the organic device, more specifically, an upper electrode, or another layer provided thereon.

The protective film is, for example, a film made of silicon nitride or silicon nitride oxide, or a film which is made thereof and is further added with hydrogen. The protective film is formed by a sputtering method or a CVD method.

In some cases, another member such as a glass member, which is used as a cover glass, or a resin member is provided on the protective film.

The organic device mounted in the organic EL device element includes the pair of electrodes and the organic compound layer, i.e., light emitting layer, interposed therebetween. In this case, the protective film is provided so as to cover the organic device (organic EL device).

The organic FET at least includes a source electrode, a gate electrode, a drain electrode, and an organic semiconductor layer provided between the source electrode and the drain electrode. The protective film may be provided on the gate electrode side or provided on the side opposite to the gate electrode.

Plural organic devices may be separated from each other on the surface of the substrate. The structure in which the plural organic devices are provided within a same surface is referred to as an organic device array.

The protective film may be provided across the plural organic devices. That is, the protective film may be provided to cover the organic device array. In this case, in order to further protect the organic device array, it is desirable to provide the protective film even outside the organic device array, that is, to provide the protective film with an area larger than an array area.

The protective film can be desirably provided on a large array whose array area is equal to or larger than two-inch square. When the array becomes larger, the improvement of the moisture resistance performance which is a characteristic of the protective film is stringently required. Therefore, the protective film in this embodiment is desirably used.

A large number of substrates can be provided on plural corresponding electroconductive rear plates for film formation.

When film formation is to be performed on the large array or the plural substrates, it is desirable to direct the film-formed surface downward in view of substrate treatment.

### EXAMPLE

An organic EL device was manufactured on a two-inch square TFT substrate by using the following known materials. That is, the TFT substrate on which a first electrode made of Cr was provided was subjected to UV/ozone cleaning. An organic light emitting layer including a hole transporting layer, a light emitting layer, an electron transporting layer, and an electron injecting layer was formed on the TFT substrate using the following respective materials by a vacuum vapor deposition method.

A film made of αNPD represented by the following chemical formula (1) was formed at a film thickness of 50 nm to serve as the hole transporting layer.

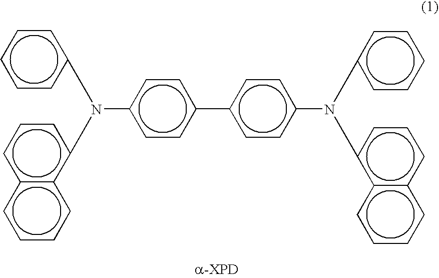

Co-deposition from the vapor was conducted at a weight ratio of 100:6 of aluminum chelate complex (Alq3) represented by the following chemical formula (2) to coumarin 6 represented by the following chemical formula (3) to form the light emitting layer having a film thickness of 50 nm.

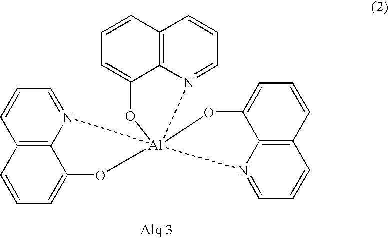

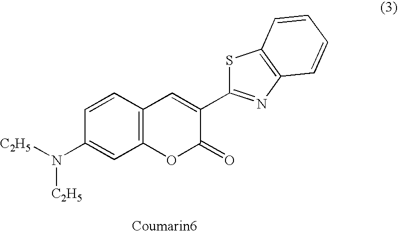

A film made of phenanthroline compound represented by the following chemical formula (4) was formed at a film thickness of 10 nm to serve as the electron transporting layer.

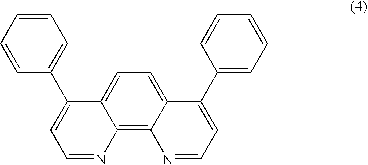

Co-deposition from the vapor was conducted at a weight ratio of 100:1 of phenanthroline compound to cesium carbonate (Cs₂CO₃) to form the electron injecting layer having a film thickness of 40 nm.

A second electrode of an ITO thin film was formed on the organic light emitting layer at a film thickness of 220 nm by a sputtering method to produce a pixel.

After that, in the apparatus shown in FIG. 1, a passivation film (protective film) was formed on the organic device substrate W₁ at a film thickness of 700 nm by a PE-CVD method while bias voltages were applied to the electroconductive rear plate 11 provided on the rear side of the substrate.

The organic device element corresponds to a large array whose array area is equal to or larger than two-inch square (substantially square area in which diagonal line length was equal to or larger than two inches). The organic device was provided on the substrate, so that the area of the substrate was larger than the array area and each side thereof was 90 mm in length.

The passivation film was formed in the chamber 10 by the gas supply unit 10a, the discharge unit 12, and the exhaust unit 10b at room temperature in a condition in which an SiH₄ gas flow rate was 4 sccm, an N₂ gas flow rate was 200 sccm, high-frequency power was 40 W, and a pressure was 70 Pa. At this time, −10 V and −5 V, each of which was a direct current voltage, were applied to a first electroconductive part and a second electroconductive part, respectively, of the electroconductive rear plate 11 provided on the rear surface of the substrate. The first electroconductive part corresponds to a central portion of 60 mm square (square whose side was 60 mm in length) and the second electroconductive part corresponds to a peripheral portion which was electrically insulated from the central portion and has a peripheral width of 30 mm.

The substrate was overlapped with an inside of the first electroconductive part corresponding to the central portion.

A sample manufactured by the above-mentioned processing was subjected to an endurance test at a constant temperature of 60° C. and a high humidity of 90%. After the lapse of a predetermined time, light emission was performed to measure the number of dark spots. No dark spot was detected during a constant-temperature high-humidity endurance time of 1000 hours.

### COMPARATIVE EXAMPLE

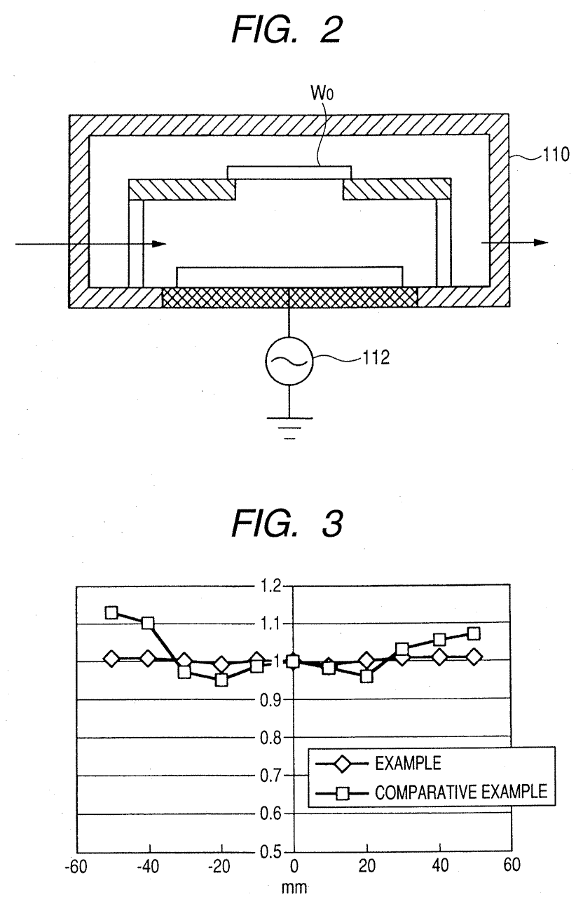

An organic device substrate W₀ obtained after the second electrode was formed by the same method as that in the example was introduced into a chamber 110 shown in FIG. 2. While the bias voltages were not applied to the organic device substrate W₀, high-frequency power was applied to a discharge unit 112 to form a passivation film (protective film) in the same manner as that in the example. A sample manufactured by the above-mentioned processing was subjected to an endurance test at a constant temperature of 60° C. and a high humidity of 90%. After the lapse of a predetermined time, light emission was performed to measure the number of dark spots. Dark spots were detected after the lapse of a constant-temperature high-humidity endurance time of 100 hours.

As can be determined from the above-mentioned results, the protective film formed in the organic device element with the application of the bias voltages distributed on the rear surface of the substrate has higher moisture resistance performance than the protective film formed in the organic device element without the application of the bias voltages.

A film thickness distribution of the protective film of the organic EL sample manufactured by the method according to the example was measured. As a result, it was found that a variation in film thickness was in a range of ±2%.

A film thickness distribution of the protective film of the organic EL sample manufactured by the method according to the comparative example was measured. As a result, it was found that a variation in film thickness was ±10%. It was confirmed that the protective film of this sample includes a thick peripheral portion and a thin center portion. FIG. 3 is a graph illustrating the film thickness distributions in the example and the comparative example.

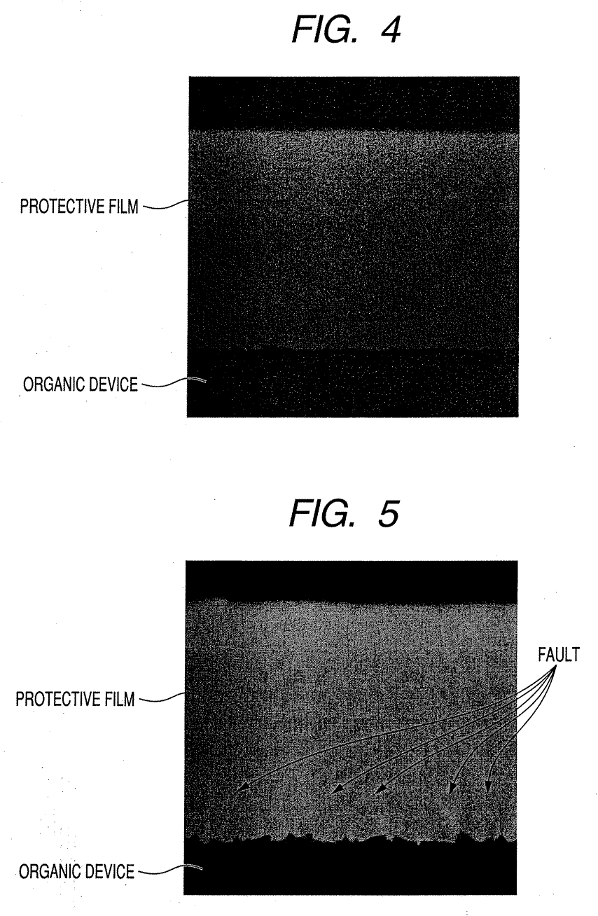

Next, cross sections at plural portions randomly selected, of the protective films of the organic EL samples manufactured in the example and the comparative example were observed using a TEM. A magnification of each of the cross sectional photographs is 100,000 times. In the case of the organic EL sample obtained in Example 1, it could be confirmed at any observed portions that smooth film formation was performed in a uniform film thickness between an interface with the organic device corresponding to a lower layer and the surface of the protective film corresponding to an upper layer. An example is shown in FIG. 4.

In contrast, in the case of the organic EL sample manufactured by the method according to the comparative example, as shown in FIG. 5, it was confirmed that faults were caused from the interface with the organic device corresponding to the lower layer toward the surface of the protective film between the thick peripheral portion and the thin center portion of the protective film.

As is apparent from the above-mentioned results, the film formation method of attaining the uniform film thickness distribution according to the present invention is a method capable of providing a film which includes no fault and has uniform film quality as the protective film, that is, a method capable of obtaining an unexpected effect.

While the present invention has been described with reference to embodiments, it is to be understood that the invention is not limited to the disclosed embodiments. The scope of the following claims is to be accorded the broadest interpretation so as to encompass all such modifications and equivalent structures and functions.

This application claims the benefit of Japanese Patent Application No. 2006-092893, filed Mar. 30, 2006, and Japanese Patent Application No. 2007-010959, filed Jan. 22, 2007, which are hereby incorporated by reference herein in their entirety.

What is claimed is:

1. A method of manufacturing an organic device element comprising a substrate, an organic device, and a protective film covering the organic device, the organic device comprising a pair of electrodes and an organic compound layer provided between the pair of electrodes,
the method comprising forming the protective film on the organic device provided on the substrate,
wherein the protective film is formed on the organic device provided on the substrate while separate bias voltages are applied to a central region overlapped with the substrate and a peripheral region corresponding to a peripheral portion of the central region, of an electroconductive member provided on a rear side of the substrate.
